(19) United States
(12) Patent Application Publication
(10) Pub. No.: US 2026/0028710 A1
(43) Pub. Date: Jan. 29, 2026

(54) METHOD OF MANUFACTURING PLASMA-RESISTANT MULTILAYER COATING FILM

(71) Applicant: Samsung Electronics Co., Ltd., Suwon-si (KR)

(72) Inventors: Jiyeon Baek, Suwon-si (KR); Jongbeom Lee, Incheon (KR); Taeyoon Park, Suwon-si (KR); Jinho Jo, Suwon-si (KR); Sunho Kim, Suwon-si (KR); Youngjune Park, Suwon-si (KR); Minkwang Jeon, Gumi-si (KR); Hoon Jeong, Gumi-si (KR); Byeonguk Moon, Gumi-si (KR); Seungyoung Oh, Gumi-si (KR)

(73) Assignees: Samsung Electronics Co., Ltd., Suwon-si (KR); Green Resource Co., Ltd., Incheon (KR); Wonik Qnc Corporation, Gumi-si (KR)

(21) Appl. No.: 19/216,924

(22) Filed: May 23, 2025

(30) Foreign Application Priority Data
Jul. 24, 2024 (KR) 10-2024-0098061
Nov. 21, 2024 (KR) 10-2024-0167755

(51) Int. Cl. C23C 14/58; C23C 14/08

(52) U.S. Cl. CPC C23C 14/5833; C23C 14/083

(57) ABSTRACT

Provided is a method of manufacturing a plasma-resistant multilayer coating film, the method including performing a primary surface treatment on a surface of a base material having a pinhole, in which a base material includes at least one material selected from ceramic, metal, semiconductor, or glass, depositing a preliminary primary coating layer covering the pinhole, on the surface of the base material, performing a secondary surface treatment on the preliminary primary coating layer to form a primary coating layer, and depositing a secondary coating layer on the primary coating layer, in which the secondary surface treatment is an ion beam treatment process, and an upper surface of the primary coating layer is flattened by the secondary surface treatment.

### CROSS-REFERENCE TO RELATED APPLICATION

This application is based on and claims priority under 35 U.S.C. § 119 to Korean Patent Application No. 10-2024-0098061, filed on Jul. 24, 2024, and 10-2024-0167755, filed on Nov. 21, 2024, in the Korean Intellectual Property Office, the disclosure of which is incorporated by reference herein in its entirety.

### BACKGROUND

At least one inventive concept relates to a method of manufacturing a plasma-resistant multilayer coating film. More specifically, at least one inventive concept relates to a method of manufacturing a plasma-resistant multilayer coating film that controls surface defects of a base material including a ceramic, metal, semiconductor, or glass.

In semiconductor manufacturing, in particular, parts or members of equipment used for a plasma-based work process (e.g., etching) may be exposed to a plasma reaction atmosphere and may easily have their surfaces damaged, and thus, most of them are formed by providing a coating layer that is resistant to the plasma-based work environment. Various ceramic materials are used in semiconductor process equipment, and the degree of contamination particle generation or physical etching varies depending on the location. Currently, Y₂O₃ is widely used as a plasma-resistant material with excellent corrosion resistance, and it is mainly manufactured by applying coating technologies such as physical vapor deposition (PVD), aerosol deposition (AD), and suspension plasma spray (SPS).

### SUMMARY

At least one inventive concept provides a method of manufacturing a multilayer coating film having excellent plasma resistance properties and effectively controlling surface defects. The problem to be addressed is not limited to the problems mentioned above, and other problems may be clearly understood by those skilled in the art from the description below.

At least one inventive concept provides a method of manufacturing a plasma-resistant multilayer coating film in order to achieve the technical objective.

According to at least one inventive concept, there is provided a method of manufacturing a plasma-resistant multilayer coating film, the method including performing a primary surface treatment on a surface of a base material having a pinhole, in which the base material includes a material selected from at least one of ceramic, metal, semiconductor, or glass, depositing a preliminary primary coating layer covering the pinhole, on the surface of the base material, performing a secondary surface treatment on the preliminary primary coating layer to form a primary coating layer, and depositing a secondary coating layer on the primary coating layer, wherein the secondary surface treatment is an ion beam treatment process, and an upper surface of the primary coating layer is flattened by the secondary surface treatment.

According to at least one inventive concept, there is provided a method of manufacturing a plasma-resistant multilayer coating film, the method including (a) performing a primary surface treatment on a surface of a base material having a pinhole, in which the base material includes a material selected from at least one of ceramic, metal, semiconductor, or glass, (b) depositing a coating layer covering the pinhole, on the surface of the base material, (c) flattening an upper surface of the coating layer by an ion beam treatment process, (d) depositing an additional coating layer on the coating layer, and (c) repeating operations (c) and (d) n times, in which n is a natural number greater than or equal to 1, wherein when performing operation (c), an internal pressure and internal temperature of a process chamber are 1×10⁻⁴ torr to 3×10⁻³ torr and 300 K to 600 K, respectively, and the ion beam has a current of 00 mA to 400 mA and an acceleration voltage of 800 V to 1000 V.

According to at least one inventive concept, there is provided a method of manufacturing a plasma-resistant multilayer coating film, the method including performing a primary surface treatment on a surface of a base material having a pinhole, in which the base material includes a material selected from at least one of ceramic, metal, semiconductor, or glass, depositing a plurality of coating layers over the base material covering the pinhole to form a coating laminate, and depositing an uppermost coating layer on the coating laminate, wherein the forming of the coating laminate further includes flattening an upper surface of an upper coating layer of the plurality of coating layers by performing an ion beam treatment process on an upper surface of each corresponding coating layer after each coating layer is deposited, and when performing the ion beam treatment process, an internal pressure and internal temperature of a process chamber are 1×10⁻⁴ torr to 3×10⁻³ torr and 300 K to 600 K, respectively, and an ion beam has a current of t 200 mA to 400 mA and an acceleration voltage of 800 V to 1000 V.

According to an aspect there is provided a plasma-resistant multilayer coating film made by any of the methods herein.

### BRIEF DESCRIPTION OF THE DRAWINGS

Embodiments will be more clearly understood from the following detailed description taken in conjunction with the accompanying drawings in which:

FIGS. 1 to 4 are cross-sectional views showing a process flow of a manufacturing a plasma-resistant multilayer coating film according to an embodiment;

FIG. 5 is a graph showing results of an experiment evaluating the chemical stability of a plasma-resistant double-layer coating film according to an embodiment;

FIG. 6 is a schematic cross-sectional view of a plasma-resistant multilayer coating film according to an embodiment; and

FIG. 7 is a schematic cross-sectional view of a plasma-resistant multilayer coating film according to an embodiment.

### DETAILED DESCRIPTION OF THE EMBODIMENTS

Hereafter, inventive concepts will be fully described with reference to the accompanying drawings In the drawings, like reference numerals are used to indicate like elements and the descriptions thereof will not be repeated.

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed herein in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Spatially relative terms, such as “lower” or “upper” may be used herein for case of description to describe one element's or feature's relationship to another element(s) or feature(s) as illustrated in the figures. It will be understood that the spatially relative terms are intended to encompass different orientations of the device in use or operation in addition to the orientation depicted in the figures.

As used herein the terms “on”, “cover” and “covering” are intended to mean that an element is over or aside another element. The elements may be touching or not. For example, there may be layers between layers that are “on” one another. An element “on” or “covering” another element need not cover an entire top surface of an element below to be considered “on” or “covering”. The terms are intended to encompass one element “on” or “covering” all, or any part of, an element below it.

As used herein the terms “flat”, “flatten”, “flattening” or “flattened” do not necessarily mean an exactly flat or flattened, but are intended to encompass nearly flat or flattened within typical variations that may occur resulting from conventional manufacturing processes.

Various changes and numerous embodiments will be illustrated in the drawings and described in detail in the written description. However, this is not intended to limit the inventive concepts to particular modes of practice, and it is to be appreciated that all changes, equivalents, and substitutes that do not depart from the spirit and technical scope of the inventive concepts are encompassed in the inventive concepts. In the description of the embodiments, certain detailed explanations of related art are omitted when it is deemed that they may unnecessarily obscure the essence of the inventive concepts.

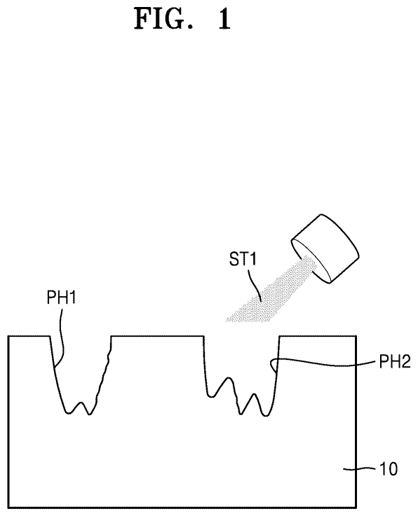

FIGS. 1 to 4 are cross-sectional views showing a process flow of a method of manufacturing a plasma-resistant multilayer coating film according to an embodiment.

Referring to FIG. 1, a base material 10 including a first pinhole PH1 and a second pinhole PH2 may be prepared. In example embodiments, the base material 10 may include one or more pinholes. Reference herein to “a pinhole” encompasses one or more pinholes. Reference to a first pinhole PH1 and/or a second pinhole PH2 is not intended to be limiting, and it should be understood that the base material may include further pinholes.

In FIG. 1, the base material 10 is illustrated as including a first pinhole PH1 and the second pinhole PH2, but this is merely an example for convenience, and the number and location of the pinholes are not limited to the illustrations of FIGS. 1 to 4.

In embodiments, the base material 10 may include a process component inside a semiconductor chamber, and may be, for example, a ceramic base material. However, the base material 10 is not limited to a ceramic base material, and may refer to a base material including at least one material selected from ceramic SiC, SiO₂, Al₂O₃, or metals Al, Fe, etc.

In embodiments, a surface roughness of the base material 10 may be in a range of about 0.001 μm to about 10 μm, or about 0.01 μm to about 5 μm, but the inventive concepts are not limited thereto.

If pinholes, such as the first and second pinholes PH1 and PH2 depicted in FIG. 1 for example, are included in the base material 10, it may be difficult to control defects on a surface of a coating in a single layer when performing an oxide coating process using a physical vapor deposition (PVD) method to implement plasma resistance. For example, in the coating process, fine pits may be formed on the surface of the coating due to bonding between particles, and the pits become weak points where plasma etching is concentrated, and a width and depth of the pits increase from that the weak point, which affects the base material and causes serious defects in mechanical stability and reliability.

Therefore, to address the above problem, an aspect may provide a method of manufacturing a plasma-resistant multilayer coating film to suppress the occurrence of pits due to the first and second pinholes PH1 and PH2, for example, of the base material 10.

Referring again to FIG. 1, in example embodiments, a primary surface treatment ST1 may be performed on a surface of the base material 10 including the first and second pinholes PH1 and PH2. In embodiments, the primary surface treatment ST1 process may be a plasma treatment or ion beam treatment process for the surface of the base material 10.

In examples, the primary surface treatment ST1 may be a process for increasing adhesion between the base material 10 and a coating to be deposited later as a pretreatment process for coating deposition.

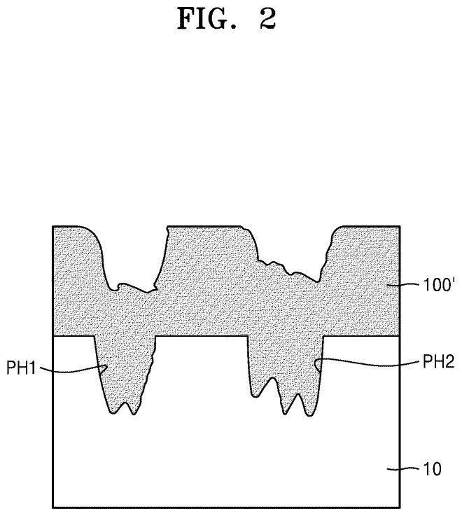

Referring to FIG. 2, a preliminary primary coating layer 100′ may be deposited on the base material 10. In some embodiments, the preliminary primary coating layer 100′ may be formed to a thickness sufficient to cover pinholes, such as the first and second pinholes PH1 and PH2. The preliminary primary coating layer 100′ may perform as a base coating layer for filling the first and second pinholes PH1 and PH2 of the base material 10. As illustrated in FIG. 2, the preliminary primary coating layer 100′ may be deposited in a shape in which an upper surface thereof is not flat due to the first and second pinholes PH1 and PH2.

In embodiments, the surface roughness of the preliminary primary coating layer 100′ may be in a range of about 0.001 μm to about 10 μm, or about 0.01 μm to about 5 μm, but examples are not limited thereto. In embodiments, the preliminary primary coating layer 100′ may be formed using at least one method selected from aerosol deposition (AD), pulse laser deposition (PLD), physical vapor deposition (PVD), chemical vapor deposition (CVD), or atomic layer deposition (ALD).

In embodiments, the preliminary primary coating layer 100′ may include Al₂O₃, ZrO₂, Y₂O₃, or SiC pure materials. In embodiments, the preliminary primary coating layer 100′ may include a composite compound including Al₂O₃, ZrO₂, or Y₂O₃ at a molar fraction of 10% or more or a molar fraction of 12% or more.

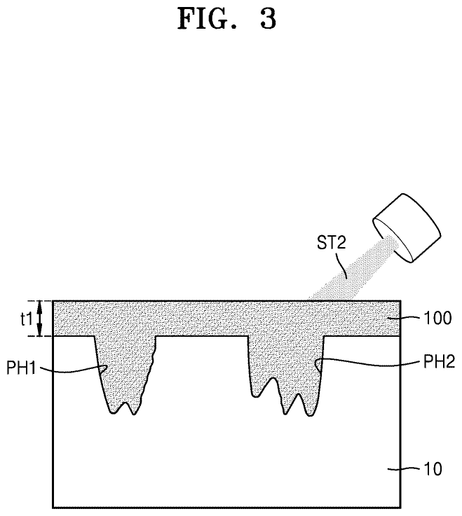

Referring to FIG. 3, a secondary surface treatment ST2 may be performed on the resulting product of FIG. 2 to flatten the preliminary primary coating layer 100′ into a primary coating layer 100.

In embodiments, the secondary surface treatment ST2 may be an ion beam treatment process. Using an ion beam, surface defects including pits formed by transferring the first and second pinholes PH1 and PH2 of the base material 10 to the preliminary primary coating layer 100′ may be removed, and the upper surface of the preliminary primary coating layer 100′ may be flattened.

A thickness of the primary coating layer 100 obtained by the secondary surface treatment ST2 may be a minimum thickness of 50 μm or less, or 40 μm or less. In the case of the primary coating layer 100, an upper surface thereof may be flattened by the secondary surface treatment ST2, but a depth of a lower surface thereof may not be constant due to pinholes, such as the first and second pinholes PH1 and PH2. Therefore, the formed thickness of the primary coating layer 100 may vary depending on a region, and a first thickness t1, which is the thickness between an uppermost surface of the base material 10 and the upper surface of the primary coating layer 100 may not be greater than 50 μm or 40 μm based on the upper surface of the base material 10 where there are no pinholes PH1 and PH2.

In embodiments, when an ion beam treatment process used for the secondary surface treatment ST2 is performed, the internal pressure of a process chamber may be in a range of about 1×10⁻⁴ torr to about 3×10⁻³ torr or about 1.5×10⁻⁴ torr to about 2.5×10⁻³ torr. In embodiments, when the ion beam treatment process used for the secondary surface treatment ST2 is performed, the internal temperature of the process chamber may be in the range of about 300 K to about 600 K or about 350 K to about 550 K. In embodiments, when performing an ion beam treatment process used for the secondary surface treatment ST2, at least one of argon gas, oxygen gas, nitrogen gas, or any combination selected from among these gases may be used. In embodiments, when performing the secondary surface treatment ST2, an ion beam having an acceleration voltage of about 800 V to about 1000 V and a current of about 200 mA to about 400 mA may be used. In embodiments, an ion beam having an acceleration voltage of about 850 V to about 950 V and a current of about 250 mA to about 350 mA may be used.

The ion beam treatment process may be performed under the conditions described above, but the inventive concepts are not limited thereto.

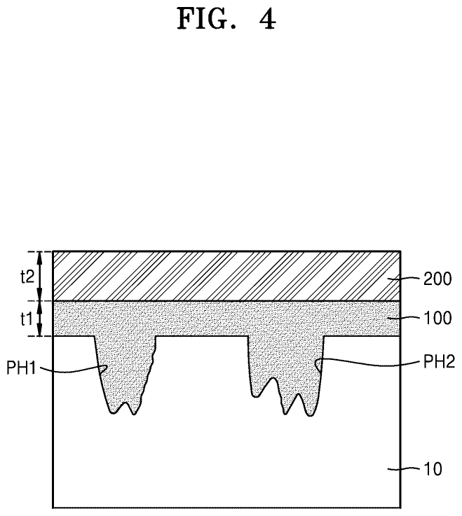

Referring to FIG. 4, a secondary coating layer 200 may be formed on the primary coating layer 100. Although not shown in FIG. 4, a surface treatment operation for removing byproducts on the surface of the secondary coating layer 200 after forming the secondary coating layer 200 may be additionally performed.

In embodiments, the surface roughness of the secondary coating layer 200 may be in a range of about 0.001 μm to about 10 μm, or about 0.01 μm to about 5 μm, but examples are not limited thereto. In embodiments, the secondary coating layer 200 may be formed using at least one method selected from PLD, PVD, CVD, or ALD.

In exemplary embodiments, the secondary coating layer 200 may include a pure material of Al₂O₃, ZrO₂, Y₂O₃, or SiC. In embodiments, the secondary coating layer 200 may include a composite compound including Al₂O₃, ZrO₂, and/or Y₂O₃ at a molar fraction of 10% or more or a molar fraction of 12% or more. In some embodiments, a material included in the secondary coating layer 200 may be the same as the material included in the primary coating layer 100. In some other embodiments, the material included in the secondary coating layer 200 may have different components from the material included in the primary coating layer 100, or in the case of a composite compound, at least some components may be included in different ratios even if the same components are included.

In embodiments, the secondary coating layer 200 may have a flat upper surface. A second thickness t2, which is a thickness of the secondary coating layer 200 formed on the primary coating layer 100, may not be greater than 50 μm. In embodiments, the second thickness t2 may be the same as or different from the first thickness t1. A size relationship between the first thickness t1 and the second thickness t2 does not limit the technical idea of the inventive concepts.

Referring to FIGS. 1 to 4, a method of manufacturing a plasma-resistant multilayer coating film according to example embodiments has been described. Examples may implement a plasma-resistant coating film having excellent mechanical stability by utilizing the coating of the primary coating layer 100 to suppress the occurrence of defects caused by pinholes, such as the first and second pinholes PH1 and PH2 of the base material 10, and the coating of the secondary coating layer 200 to control peeling defects and surface pitting defects that may not be completely controlled by a single-layer plasma-resistant coating film.

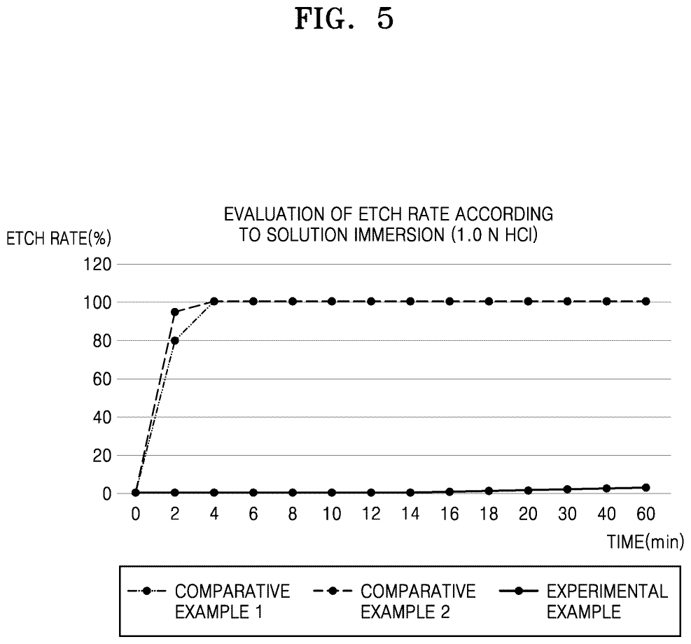

FIG. 5 is a graph showing the results of an experiment evaluating the chemical stability of the plasma-resistant double-layer coating film of an example embodiment.

Comparative Example 1, Comparative Example 2, and Experimental Example were all prepared by forming a two-layer coating film structure using a physical vapor deposition method on the base material. In each of the primary coating layer and the secondary coating layer, Y₂O₃ was used. In Comparative Example 1, the primary coating layer was formed by physical vapor deposition, and then the secondary coating layer was also formed by physical vapor deposition without a separate flattening operation. In Comparative Example 2, the primary coating layer was formed by physical vapor deposition, and then mechanical flattening, i.e., polishing operation, was performed, and then the secondary coating layer was formed by physical vapor deposition. In the Experimental Example, the primary coating layer was formed on the base material using physical vapor deposition, and then an ion beam treatment process was performed as described above, and then the secondary coating layer was formed by physical vapor deposition. For example, the ion beam treatment process performed for the Experimental Example may be the secondary surface treatment ST2 process described with reference to FIG. 3.

The degree of erosion of each coating film by immersing the coating films of Comparative Example 1, Comparative Example 2, and the Experimental Example in a 1.0 N HCl solution is shown in the graph of FIG. 5. The immersion experiment was conducted at room temperature 25° C.

Referring to FIG. 5, in Comparative Example 1, in which a two-layer coating film was formed without separate surface treatment, it confirmed that an erosion phenomenon of about 80%, in which the coating was peeled off, occurred in about 2 minutes after immersion in the HCl solution, and in Comparative Example 2, in which a mechanical flattening operation has been performed on the primary coating layer before forming the secondary coating layer, it confirmed that an erosion phenomenon of about 95%, in which the coating was peeled off, occurred in about 2 minutes after immersion in the same HCl solution. It was confirmed that both Comparative Examples 1 and 2 had an unstable interface between the primary coating layer and the secondary coating layer, which easily caused the coating to peel off, and thus caused rapid erosion.

On the other hand, in the case of an Experimental Example including a two-layer coating film structure obtained by performing the ion beam treatment process described with reference to FIG. 3 before forming the primary coating layer and forming the secondary coating layer, the results showed that after 60 minutes of immersion in HCl solution, approximately 3% of surface etching occurred without any interfacial peeling, and as a result, compared to Comparative Examples 1 and 2, it was confirmed that the interface was stable and the peeling resistance was high, and the chemical properties and mechanical stability were excellent due to the characteristics of the physical vapor deposition coating film.

When a coating film is formed by spray deposition alone, there is an advantage in that a coating film without pits on a surface may be obtained, but due to the characteristics of the spray deposition method that forms a film by physical collision, stress may be concentrated in a specific region inside the coating, and thus, a part of the coating film may be broken when a plasma process is performed later. Therefore, because the coating peel off may easily occur, so it may be difficult to implement a plasma-resistant coating film.

On the other hand, when a coating film is formed by a physical vapor deposition process alone, it may be advantageous compared to a coating film formed by spray deposition in terms of stress, but disadvantageously pits may easily form on the coating surface, and the pits may cause a phenomenon of process by-products being caught. As a result, the coating film may peel off preferentially in a corresponding region, and thus, it may be difficult to implement a coating film with excellent stability using physical vapor deposition.

Therefore, because a single coating film may have disadvantages regardless of the deposition method, according to an example, a plasma-resistant multilayer coating film with excellent chemical properties and mechanical stability may be implemented while supplementing the above problems.

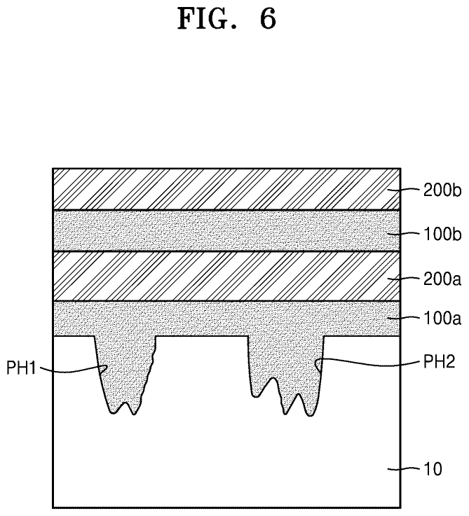

FIG. 6 is a cross-sectional view of a plasma-resistant multilayer coating film according to an example.

It will be understood that the plasma-resistant multilayer coating film of FIG. 6 is not mutually exclusive with the plasma-resistant multilayer coating film described with reference to FIG. 4, and elements having the same reference numerals are the same components. Hereinafter, overlapping descriptions of the same components are omitted, and differences from the plasma-resistant multilayer coating film of FIG. 4 will be mainly described.

Unlike the plasma-resistant multilayer coating film of FIG. 4, which is formed as a double film, the plasma-resistant multilayer coating film of FIG. 6 has a laminated structure formed by alternately repeating the primary coating layer 100 and the secondary coating layer 200. In FIG. 6, the primary coating layer 100 and the secondary coating layer 200 are shown to be laminated twice each, but this is only an example, and each layer may be formed alternately three or more times. For example, the primary coating layer 100 and the secondary coating layer 200 may be laminated two to eight times each.

Referring to FIG. 6, a lower primary coating layer 100a may be formed on the base material 10 including the first and second pinholes PH1 and PH2, and a lower secondary coating layer 200a, an upper primary coating layer 100b, and an upper secondary coating layer 200b may be sequentially formed thereon.

In embodiments, the lower secondary coating layer 200a and the upper secondary coating layer 200b may be formed with the same composition and the same deposition method as the secondary coating layer 200 of FIG. 4. In embodiments, the lower primary coating layer 100a and the upper primary coating layer 100b may be formed with the same composition as the primary coating layer 100 of FIG. 4.

The lower primary coating layer 100a may be formed using the same deposition method as the primary coating layer 100 of FIG. 4, for example, at least one method selected from spray deposition, pulsed laser deposition, physical vapor deposition, chemical vapor deposition, or atomic layer deposition. The upper primary coating layer 100b may be formed using at least one method selected from the remaining deposition methods except for spray deposition, unlike the lower primary coating layer 100a.

For example, when the plasma-resistant multilayer coating film includes a structure of three or more layers, spray deposition may be used when forming a layer that directly covers the first and second pinholes PH1 and PH2, for example, a coating layer disposed at the lowest position, but spray deposition may not be used when forming the remaining coating layers except for the coating layer disposed at the lowest position.

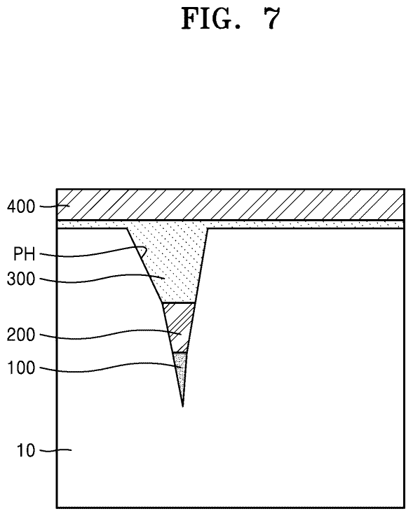

FIG. 7 is an example cross-sectional view of a plasma-resistant multilayer coating film according to an example.

It will be understood that the plasma-resistant multilayer coating film of FIG. 7 is not mutually exclusive with the plasma-resistant multilayer coating film described with reference to FIG. 4, and elements having the same reference numerals are the same components. Hereinafter, overlapping descriptions of the same components are omitted, and differences from the plasma-resistant multilayer coating film of FIG. 4 will be mainly described.

Referring to FIG. 7, a deep pinhole PH that may not be sufficiently covered by a single layer may be included in the base material 10. In this case, unlike those illustrated in FIG. 4 and FIG. 6, a portion of the primary coating layer 100, the secondary coating layer 200, and the tertiary coating layer 300 may be required to stably cover the pinhole PH. Although, in FIG. 7, it is illustrated that a total of three coating layers covers the pinhole PH, this is merely an example, and the inventive concepts are not limited thereto. For example, four or more coating layers may be required to cover the deep pinhole PH.

In embodiments, the primary coating layer 100, the secondary coating layer 200, and the tertiary coating layer 300 may each be formed using at least one method selected from spray deposition, pulsed laser deposition, physical vapor deposition, chemical vapor deposition, or atomic layer deposition.

In embodiments, the surface roughness of the primary coating layer 100, the secondary coating layer 200, and the tertiary coating layer 300 may each be in a range of about 0.001 μm to about 10 μm, or about 0.01 μm to about 5 μm, but the inventive concepts are not limited thereto.

In embodiments, the primary coating layer 100, the secondary coating layer 200, and the tertiary coating layer 300 may each include a pure material of Al₂O₃, ZrO₂, Y₂O₃, or SiC. In embodiments, the primary coating layer 100, the secondary coating layer 200, and the tertiary coating layer 300 may each include a composite compound containing Al₂O₃, ZrO₂, and/or Y₂O₃ at a molar fraction of 10% or more or a molar fraction of 12% or more.

After forming the tertiary coating layer 300 that covers the remaining space of the deep pinhole PH and the upper surface of the base material 10, an ion beam may be used to flatten the surface of the tertiary coating layer 300 before depositing a quaternary coating layer 400. The ion beam treatment process performed at this time may be a process corresponding to the secondary surface treatment ST2 process described with reference to FIG. 3.

In embodiments, when the ion beam treatment process is performed, the internal pressure of the process chamber may be in a range of about 1×10⁻⁴ torr to about 3×10⁻³ torr or about 1.5×10⁻⁴ torr to about 2.5×10⁻³ torr. In embodiments, when the ion beam treatment process is performed, the internal temperature of the process chamber may be in a range of about 300 K to about 600 K or about 350 K to about 550 K. In embodiments, when the ion beam treatment process is performed, at least one of argon gas, oxygen gas, nitrogen gas, or a combination selected from among them may be used. In embodiments, an ion beam having an acceleration voltage in a range of about 800 V to about 1000 V and a current of about 200 mA to about 400 mA may be used. In embodiments, an ion beam having an acceleration voltage of about 850 V to about 950 V and a current of about 250 mA to about 350 mA may be used.

Surface defects such as pits formed by transferring deep pinholes PH of the base material 10 included in the tertiary coating layer 300 by the ion beam treatment process may be removed.

After surface treatment of the tertiary coating layer 300 is completed by the ion beam treatment process, the quaternary coating layer 400 may be additionally formed. At this time, the surface roughness of the quaternary coating layer 400 may be in the range of about 0.001 μm to about 10 μm, or about 0.01 μm to about 5 μm, and a thickness may not exceed 50 μm or 40 μm.

In embodiments, the quaternary coating layer 400 may be formed using at least one method selected from pulsed laser deposition, physical vapor deposition, chemical vapor deposition, or atomic layer deposition. In embodiments, the quaternary coating layer 400 may include a pure material of Al₂O₃, ZrO₂, Y₂O₃, or SiC. Alternatively, the quaternary coating layer 400 may include a composite compound including Al₂O₃, ZrO₂, and/or Y₂O₃ at a molar fraction of 10% or more or a molar fraction of 12% or more.

After forming the quaternary coating layer 400, a surface treatment operation to remove by-products, etc. from a surface of the quaternary coating layer 400 may be additionally performed, and although not shown in FIG. 7, another coating layer may be additionally deposited on the quaternary coating layer 400.

Non-limiting examples relate to a multilayer coating film including two or more layers as described above, which may address problems such as by-product entrapment and pitting that may occur when applying a single-layer coating film, may remove surface defects that may remain in a lower coating layer through a surface treatment process using an ion beam, and, at the same time, may further improve interfacial bonding stability by depositing an upper coating layer after flattening an upper surface of the lower coating layer.

While inventive concepts have been particularly shown and described with reference to embodiments thereof, it will be understood that various changes in form and details may be made therein without departing from the spirit and scope of the following claims.

What is claimed is:

1. A method of manufacturing a plasma-resistant multilayer coating film, the method comprising:
performing a primary surface treatment on a surface of a base material having a pinhole, wherein the base material comprises a material selected from the group consisting of ceramic, metal, semiconductor, and glass;
depositing a preliminary primary coating layer covering the pinhole, on the surface of the base material;
performing a secondary surface treatment on the preliminary primary coating layer to form a primary coating layer; and
depositing a secondary coating layer on the primary coating layer,
wherein the secondary surface treatment comprises an ion beam treatment process, and
an upper surface of the primary coating layer is flattened by the secondary surface treatment.

2. The method of claim 1, wherein an ion beam in the ion beam treatment process has an acceleration voltage of 800 V to 1000 V and a current of 200 mA to 400 mA.

3. The method of claim 1, wherein
the depositing of a preliminary primary coating layer is performed by at least one method selected from the group consisting of aerosol deposition, pulse laser deposition (PLD), physical vapor deposition (PVD), chemical vapor deposition (CVD), and atomic layer deposition (ALD), and
the depositing of the secondary coating layer is performed by at least one method selected from the group consisting of pulse laser deposition, physical vapor deposition, chemical vapor deposition, or atomic layer deposition.

4. The method of claim 1, wherein
a first distance between an uppermost surface of the base material and an upper surface of the primary coating layer is not greater than 50 μm, and a second distance between the upper surface of the primary coating layer and an upper surface of the secondary coating layer is not greater than 50 μm.

5. The method of claim 1, wherein, when performing the secondary surface treatment, an internal pressure of a process chamber is 1×10⁴ torr to 3×10−3 torr.

6. The method of claim 1, wherein,
when performing the secondary surface treatment, an internal temperature of a process chamber is in a range of 300 K to 600 K.

7. The method of claim 1, wherein,
performing the secondary surface treatment includes at least one gas selected from the group consisting of argon gas, oxygen gas, nitrogen gas, and combinations thereof.

8. The method of claim 1, wherein a first surface roughness of the primary coating layer is 0.001 μm to 10 μm and a second surface roughness of the secondary coating layer is 0.001 μm to 10 μm.

9. The method of claim 1, wherein a third surface roughness of the base material is 0.001 μm to 10 μm.

10. The method of claim 1, wherein the primary surface treatment comprises at least one treatment selected from the group consisting of a plasma process and an ion beam treatment process.

11. The method of claim 1, wherein the base material comprises at least one material selected from the group consisting of SiC, SiO₂, Al₂O₃, Al, and Fe.

12. The method of claim 1, wherein
the primary coating layer and the secondary coating layer each comprise a pure material selected from the group consisting of Al₂O₃, ZrO₂, Y₂O₃, and SiC, or a composite compound including at least one material selected from the group consisting of Al₂O₃, ZrO₂, and Y₂O₃, in an amount of 10% or more based on a mole fraction.

13. A method of manufacturing a plasma-resistant multilayer coating film, the method comprising:
(a) performing a primary surface treatment on a surface of a base material having a pinhole, wherein the base material comprises a material selected from the group consisting of ceramic, metal, semiconductor, and;
(b) depositing a coating layer covering the pinhole, on the surface of the base material;
(c) flattening an upper surface of the coating layer by an ion beam treatment process;
(d) depositing an additional coating layer on the coating layer; and
(e) repeating operations (c) and (d) n times, wherein n is a natural number greater than or equal to 1;
wherein when performing operation (c), an internal pressure and internal temperature of a process chamber are 1×10⁻⁴ torr to 3×10⁻³ torr and 300 K to 600 K, respectively, and
the ion beam has a current of 200 mA to 400 mA and an acceleration voltage of 800 V to 1000 V.

14. The method of claim 13, wherein a first surface roughness of the coating layer is 0.001 μm to 10 μm and a second surface roughness of the additional coating layer is 0.001 μm to 10 μm.

15. The method of claim 13, wherein a third surface roughness of the base material is in a range of 0.001 μm to 10 μm.

16. The method of claim 13, wherein
the coating layer and the additional coating layer each comprise a pure material selected from the group consisting of Al₂O₃, ZrO₂, Y₂O₃, and SiC, or a composite compound including at least one material selected from the group consisting of Al₂O₃, ZrO₂, and Y₂O₃, in an amount of 10% or more based on a mole fraction.

17. The method of claim 13, wherein the flattening of the upper surface of the coating layer includes at least one gas selected from the group consisting of argon gas, oxygen gas, nitrogen gas, and combinations thereof.

18. A method of manufacturing a plasma-resistant multilayer coating film, the method comprising:
performing a primary surface treatment on a surface of a base material having a pinhole, wherein the base material comprises a material selected from the group consisting of ceramic, metal, semiconductor, and glass;
depositing a plurality of coating layers over the base material covering the pinhole to form a coating laminate; and
depositing an uppermost coating layer on the coating laminate,
wherein the forming of the coating laminate further comprises flattening an upper surface of an upper coating layer of the plurality of coating layers by performing an ion beam treatment process on an upper surface of each corresponding coating layer after each coating layer is deposited, and
when performing the ion beam treatment process, an internal pressure and internal temperature of a process chamber are 1×10⁻⁴ torr to 3×10⁻³ torr and 300 K to 600 K, respectively, and an ion beam has a current of 200 mA to 400 mA and an acceleration voltage of 800 V to 1000 V.

19. The method of claim 18, wherein a surface roughness of each coating layer included in the coating laminate and the base material is in a range of 0.001 μm to 10 μm.

20. The method of claim 18, wherein
each coating layer of the plurality of coating layers included in the coating laminate includes a pure substance selected from the group consisting of Al₂O₃, ZrO₂, Y₂O₃, and SiC, or a complex compound including at least one material selected from the group consisting of Al₂O₃, ZrO₂, and Y₂O₃, in an amount of 10% or more by mole fraction.
